(19) United States
(12) Patent Application Publication
(10) Pub. No.: US 2025/0318365 A1
(43) Pub. Date: Oct. 9, 2025

(54) DISPLAY DEVICE, METHOD OF MANUFACTURING THE DISPLAY DEVICE, AND ELECTRONIC DEVICE

(71) Applicant: Samsung Display Co., LTD., Yongin-si (KR)

(72) Inventors: Ju Won YOON, Yongin-si (KR); Kyong Tae YU, Yongin-si (KR); Jae Been LEE, Yongin-si (KR)

(21) Appl. No.: 19/019,004

(22) Filed: Jan. 13, 2025

(30) Foreign Application Priority Data
Apr. 3, 2024 (KR) 10-2024-0045225

(51) Int. Cl. H10K 59/122; H10K 59/12; H10K 102/00

(52) U.S. Cl. CPC H10K 59/122; H10K 59/1201; H10K 2102/351

(57) ABSTRACT

A display device includes a first electrode, a first pixel-defining layer above the first electrode, a third pixel-defining layer above the first pixel-defining layer, a void between the first pixel-defining layer and the third pixel-defining layer, a light-emitting structure above the first electrode, the first pixel-defining layer, and the third pixel-defining layer, including a first layer and a second layer, and having a first area above the first pixel-defining layer, and a second area above the third pixel-defining layer, a width of the first layer at the first area being greater than a width of the second layer at the first area, and a second electrode above the light-emitting structure.

### CROSS-REFERENCE TO RELATED APPLICATION

This application claims priority to, and the benefit of, Korean Patent Application No. 10-2024-0045225, filed on Apr. 3, 2024, the content of which in its entirety is herein incorporated by reference.

### BACKGROUND

### 1. Field

The disclosure relates to a display device, a method of manufacturing the display device, and an electronic device.

### 2. Description of the Related Art

As interest in an information display is recently increased, research and development on a display device is continuously being conducted.

### SUMMARY

An aspect of the present disclosure provides a display device with improved reliability, and a method of manufacturing the display device, although the disclosure is not limited to the aspect described above, and other aspects that are not described will be clearly understood by those skilled in the art from the description below.

According to one or more embodiments, a display device includes a first electrode, a first pixel-defining layer above the first electrode, a third pixel-defining layer above the first pixel-defining layer, a void between the first pixel-defining layer and the third pixel-defining layer, a light-emitting structure above the first electrode, the first pixel-defining layer, and the third pixel-defining layer, including a first layer and a second layer, and having a first area above the first pixel-defining layer, and a second area above the third pixel-defining layer, a width of the first layer at the first area being greater than a width of the second layer at the first area, and a second electrode above the light-emitting structure.

A thickness of the second layer at the first area may be substantially uniform.

A thickness of the first layer at the first area may become thinner toward an edge thereof.

The first area of the first layer may overlap the third pixel-defining layer.

The first area of the second layer might not overlap the third pixel-defining layer.

The first area and the second area may be separated by the void.

The first layer may be between the first electrode and the second layer.

The light-emitting structure may further include a third layer above the second layer.

The third layer at the first area might not overlap the third pixel-defining layer.

The display device may further include a second pixel-defining layer between the first pixel-defining layer and the third pixel-defining layer.

A width of the second pixel-defining layer may be less than a width of the first pixel-defining layer, and may be less than a width of the third pixel-defining layer.

A side surface of the void may be defined by the second pixel-defining layer.

According to one or more embodiments, a method of manufacturing a display device includes forming a first pixel-defining layer above a first electrode, forming a third pixel-defining layer above the first pixel-defining layer, and forming a light-emitting structure above the first electrode, the first pixel-defining layer, and the third pixel-defining layer, by depositing a first layer at a first incidence angle, and depositing a second layer above the first layer at a second incidence angle that is greater than the first incidence angle.

A void may be between the first pixel-defining layer and the third pixel-defining layer.

The light-emitting structure may include a first area and a second area separated by the void, the first area being above the first pixel-defining layer, and the second area being above the third pixel-defining layer.

A thickness of the second layer at the first area may be substantially uniform.

A thickness of the first layer at the first area may become thinner toward an edge thereof.

The edge of the first layer may overlap the third pixel-defining layer.

A width of the first layer at the first area may be greater than a width of the second layer at the first area.

The method may further include forming a second pixel-defining layer between the first pixel-defining layer and the third pixel-defining layer that has a width that is less than a width of the first pixel-defining layer, and that is less than a width of the third pixel-defining layer.

According to one or more embodiments, a display device includes a processor to provide input image data, and a display device to display an image based on the input image data, the display device including sub-pixel areas, wherein the display device comprises a first electrode, a first pixel-defining layer above the first electrode, a third pixel-defining layer above the first pixel-defining layer, a void between the first pixel-defining layer and the third pixel-defining layer, a light-emitting structure above the first electrode, the first pixel-defining layer, and the third pixel-defining layer, comprising a first layer and a second layer, and having a first area above the first pixel-defining layer, and a second area above the third pixel-defining layer, a width of the first layer at the first area being greater than a width of the second layer at the first area, and a second electrode above the light-emitting structure.

Specific details of other embodiments are included in the detailed description and drawings.

According to the embodiments described above, the light-emitting structure may be separated to reduce or minimize a current flowing to adjacent sub-pixels, and to reduce or minimize a thickness dispersion of a partial layer of the light-emitting structure, thereby improving a light emission efficiency.

The embodiments are not limited to the contents described above, and further various aspects are included in the present specification.

### BRIEF DESCRIPTION OF THE DRAWINGS

The above and other aspects of the disclosure will become more apparent by describing in further detail embodiments thereof with reference to the accompanying drawings, in which:

FIG. 1 is a block diagram illustrating one or more embodiments of a display device;

FIG. 2 is a block diagram illustrating one or more embodiments of one of sub-pixels of FIG. 1;

FIG. 3 is a circuit diagram illustrating one or more embodiments of the sub-pixel of FIG. 2;

FIG. 4 is a plan view illustrating one or more embodiments of a display panel of FIG. 1;

FIG. 5 is an exploded perspective view illustrating a portion of the display panel of FIG. 4;

FIG. 6 is a plan view illustrating one or more embodiments of one of pixels of FIG. 5;

FIG. 7 is a cross-sectional view illustrating one or more embodiments taken along the line I-I′ of FIG. 6;

FIG. 8 is a cross-sectional view illustrating one or more embodiments of a light-emitting structure of FIG. 7;

FIG. 9 is a cross-sectional view illustrating one or more embodiments of a light-emitting structure included in one of first to third light-emitting elements of FIG. 7;

FIG. 10 is a cross-sectional view illustrating one or more other embodiments of the light-emitting structure included in one of first to third light-emitting elements of FIG. 7;

FIG. 11 is a plan view illustrating one or more other embodiments of one of the pixels of FIG. 5;

FIG. 12 is a plan view illustrating still one or more other embodiments of one of the pixels of FIG. 5;

FIG. 13 is a block diagram illustrating one or more embodiments of a display system;

FIG. 14 is a perspective view illustrating an application example of the display system of FIG. 13;

FIG. 15 is a diagram illustrating a head-mounted display device of FIG. 14 worn by a user; and

FIGS. 16 to 19 are cross-sectional views for each process step of a method for manufacturing a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

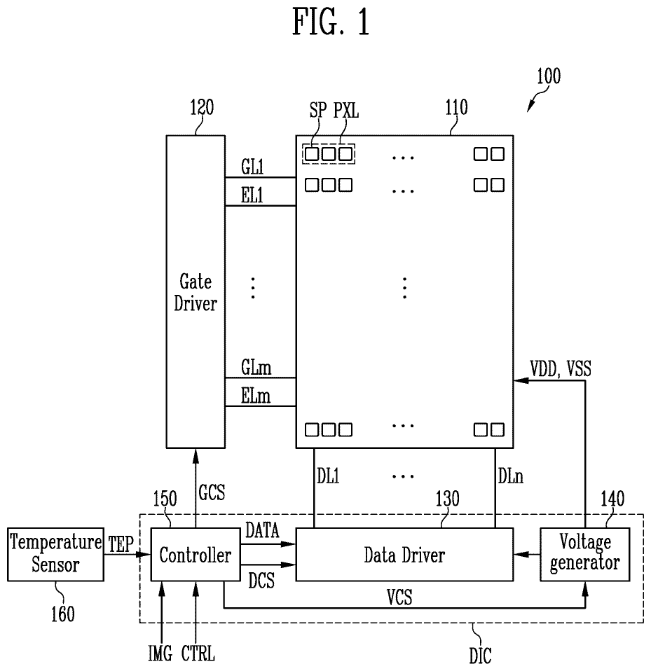

FIG. 1 is a block diagram illustrating one or more embodiments of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, each of the sub-pixels SP may generate light of a corresponding color such as red, green, blue, cyan, magenta, or yellow. Two or more sub-pixels among the sub-pixels SP may configure one pixel PXL. For example, as shown in FIG. 1, three sub-pixels SP may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm connected to the sub-pixels SP of the row direction may be further provided. In this case, the gate driver 120 may include an emission control driver configured to control the first to m-th emission control lines EL1 to Elm, and the emission control driver may operate under control of the controller 150.

The gate driver 120 may be located on one side of the display panel 110. However, embodiments are not limited thereto. For example, the gate driver 120 may be divided into two or more physically and/or logically divided drivers, and such drivers may be respectively located on one side of the display panel 110 and another side of the display panel 110 opposite the one side. As described above, the gate driver 120 may be located around the display panel 110 in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to 1 generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level that is lower than that of the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light-emitting elements of the sub-pixels SP, a reference voltage (e.g., predetermined reference voltage) may be applied to the first to n-th data lines DL1 to DLn, and the voltage generator 140 may generate such a reference voltage.

The controller 150 may control overall operations of the display device 100. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, or the controller 150 may be provided as a component distinguished from the driver integrated circuit DIC.

The display device 100 may include at least one temperature sensor 160. The temperature sensor 160 may be configured to sense a temperature around the temperature sensor 160, and to generate temperature data TEP indicating the sensed temperature. In embodiments, the temperature sensor 160 may be located adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components, such as the data driver 130 and/or the voltage generator 140.

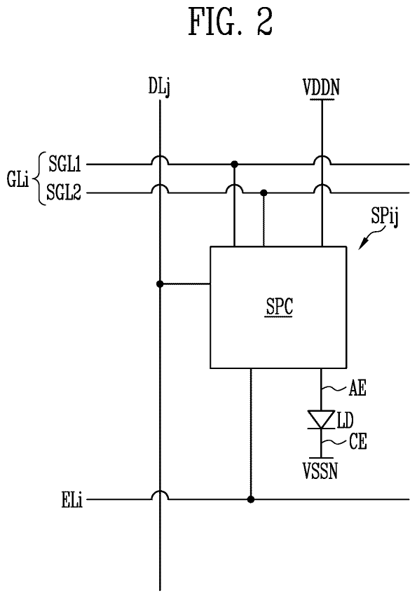

FIG. 2 is a block diagram illustrating one or more embodiments of one of the sub-pixels of FIG. 1. In FIG. 2, among the sub-pixels SP of FIG. 1, a sub-pixel SPij arranged in an i-th row (i is an integer greater than or equal to 1 and less than or equal to m) and in a j-th column (j is an integer greater than or equal to 1 and less than or equal to n) is shown as an example.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node that transmits the first power voltage VDD of FIG. 1, and the second power voltage node VSSN may be a node that transmits the second power voltage VSS of FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light-emitting element LD according to signals received through such signal lines.

The sub-pixel circuit SPC may operate in response to a gate signal received through the i-th gate line GLi. The i-th gate line GLi may include one or more sub gate lines. In embodiments, as shown in FIG. 2, the i-th gate line GLi may include first and second sub gate lines SGL1 and SGL2. The sub-pixel circuit SPC may operate in response to gate signals received through the first and second sub gate lines SGL1 and SGL2. As described above, when the i-th gate line GLi includes two or more sub-gate lines, the sub-pixel circuit SPC may operate in response to gate signals received through corresponding sub gate lines.

The sub-pixel circuit SPC may operate in response to an emission control signal received through the i-th emission control line ELi. In embodiments, the i-th emission control line ELi may include one or more sub emission control lines. When the i-th emission control line ELi includes two or more sub emission control lines, the sub-pixel circuit SPC may operate in response to emission control signals received through the corresponding sub emission control lines.

The sub-pixel circuit SPC may receive a data signal through the j-th data line DLj. The sub-pixel circuit SPC may store a voltage corresponding to the data signal in response to at least one of the gate signals received through the first and/or second sub gate lines SGL1 and/or SGL2. The sub-pixel circuit SPC may adjust a current flowing from the first power voltage node VDDN to the second power voltage node VSSN through the light-emitting element LD according to the stored voltage, in response the emission control signal received through the i-th emission control line ELi. Accordingly, the light-emitting element LD may generate light of a luminance corresponding to the data signal.

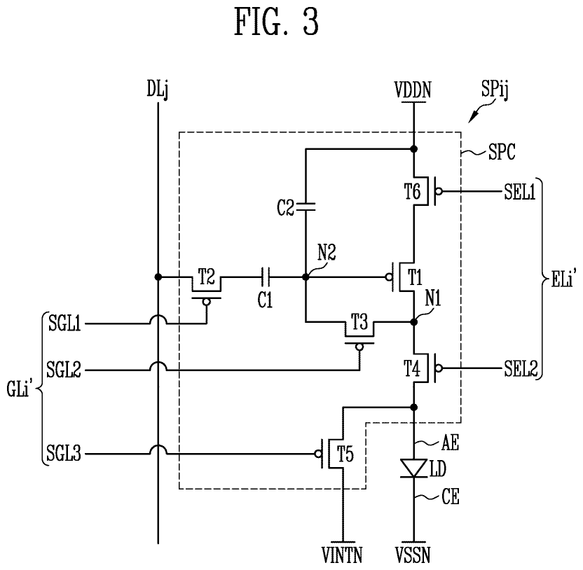

FIG. 3 is a circuit diagram illustrating one or more embodiments of the sub-pixel of FIG. 2.

Referring to FIG. 3, the sub-pixel SPij may include a sub-pixel circuit SPC and a light-emitting element LD.

The sub-pixel circuit SPC may be connected to an i-th gate line GLi′, an i-th emission control line ELi′, and the j-th data line DLj. Compared to the i-th gate line GLi of FIG. 2, the i-th gate line GLi′ may further include a third sub gate line SGL3. Compared to the i-th emission control line ELi of FIG. 2, the i-th emission control line ELi′ may include a first sub emission control line SEL1 and a second sub emission control line SEL2.

The sub-pixel circuit SPC may include first to sixth transistors T1, T2, T3, T4, T5, and T6, and first and second capacitors C1 and C2.

The first transistor T1 may be connected between the first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 may be connected to the first sub gate line SGL1, and thus the second transistor T2 may be turned on in response to a gate signal of the first sub gate line SGL1. The second transistor T2 may be referred to as a switching transistor.

The third transistor T3 may be connected between the first node N1 and the second node N2. A gate of the third transistor T3 may be connected to the second sub gate line SGL2, and thus the third transistor T3 may be turned on in response to a gate signal of the second sub gate line SGL2.

The fourth transistor T4 may be connected between the first node N1 and the anode electrode AE of the light-emitting element LD. A gate of the fourth transistor

T4 may be connected to the second sub emission control line SEL2, and thus the fourth transistor T4 may be turned on in response to an emission control signal of the second sub emission control line SEL2.

The fifth transistor T5 may be connected between the anode electrode AE of the light-emitting element LD and an initialization voltage node VINTN. The initialization voltage node VINTN may be configured to transmit an initialization voltage. In embodiments, the initialization voltage may be provided by the voltage generator 140 of FIG. 1. In other embodiments, the initialization voltage may be provided by an external device of the display device 100. A gate of the fifth transistor T5 may be connected to the third sub gate line SGL3, and thus the fifth transistor T5 may be turned on in response to a gate signal of the third sub gate line SGL3.

The sixth transistor T6 may be connected between the first power voltage node VDDN and the first transistor T1. A gate of the sixth transistor T6 may be connected to the first sub emission control line SEL1, and thus the sixth transistor T6 may be turned on in response to an emission control signal of the first sub emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1, T2, T3, T4, T5, and T6, and the first and second capacitors C1 and C2. However, embodiments are not limited thereto. The sub-pixel circuit SPC may be implemented as one of various types of circuits including a plurality of transistors and one or more capacitors. For example, the sub-pixel circuit SPC may include two transistors and one capacitor. According to embodiments of the sub-pixel circuit SPC, the number of sub gate lines included in the i-th gate line GLi′ and the number of sub emission control lines included in the i-th emission control line ELi′ may vary.

The first to sixth transistors T1, T2, T3, T4, T5, and/or T6 may be P-type transistors. Each of the first to sixth transistors T1, T2, T3, T4, T5, and/or T6 may be a metal oxide silicon field effect transistor (MOSFET). However, embodiments are not limited thereto. For example, one or more of the first to sixth transistors T1, T2, T3, T4, T5, and/or T6 may be replaced with an N-type transistor.

In embodiments, the first to sixth transistors T1, T2, T3, T4, T5, and/or T6 may include an amorphous silicon semiconductor, a monocrystalline silicon semiconductor, a polycrystalline silicon semiconductor, an oxide semiconductor, and the like.

The light-emitting element LD may include the anode electrode AE, the cathode electrode CE, and a light-emitting layer. The light-emitting layer may be located between the anode electrode AE and the cathode electrode CE. After the data signal transmitted through the j-th data line DLj is reflected in the voltage of the second node N2, when the emission control signals of the first and second sub emission control lines SEL1 and SEL2 are enabled to a low level, the fourth and sixth transistors T4 and T6 may be turned on. The first transistor T1 may be turned on according to the voltage of the second node N2, and thus a current may flow from the first power voltage node VDDN to the second power voltage node VSSN. The light-emitting element LD may emit light according to an amount of the flowing current.

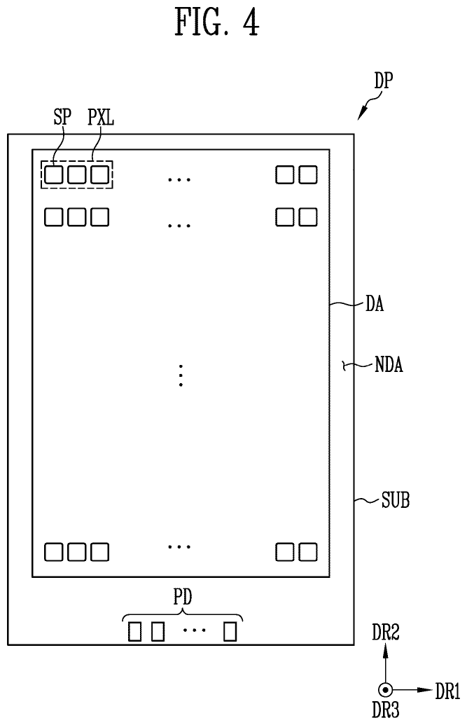

FIG. 4 is a plan view illustrating one or more embodiments of the display panel of FIG. 1.

Referring to FIG. 4, one or more embodiments DP of the display panel 110 of FIG. 1 may include the display area DA and a non-display area NDA. The display panel DP may display an image through the display area DA. The non-display area NDA may be located around the display area DA (e.g., in plan view). The display panel DP may include a substrate SUB, the sub-pixels SP, and pads PD.

When the display panel DP is used as a display screen of a head-mounted display (HMD), a virtual reality (VR) device, a mixed reality (MR) device, an augmented reality (AR) device, or the like, the display panel DP may be positioned relatively very close to user's eyes. In this case, sub-pixels SP of a relatively high integration degree may be required. To increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDoS) display device.

The sub-pixels SP may be located in the display area DA on the substrate SUB. The sub-pixels SP may be arranged in a matrix shape along a first direction DR1, and along a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ shape (PENTILE™ being a registered trademark of Samsung Display Co., Ltd., Republic of Korea). The first direction DR1 may be a row direction, and the second direction DR2 may be a column direction. Two or more sub-pixels among the plurality of sub-pixels SP may configure one pixel PXL.

A component for controlling the sub-pixels SP may be located in the non-display area NDA on the substrate SUB. For example, lines connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP, and may be located in the non-display area NDA. In other embodiments, the gate driver 120 may be implemented as an integrated circuit separated from the display panel DP. In embodiments, the temperature sensor 160 may be located in the non-display area NDA to sense a temperature of the display panel DP.

The pads PD may be located in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). In embodiments, voltages and signals suitable for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member, such as an anisotropic conductive film. At this time, the circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes, such as a polygon, a circle, a semicircle, and an ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials having a flexible property.

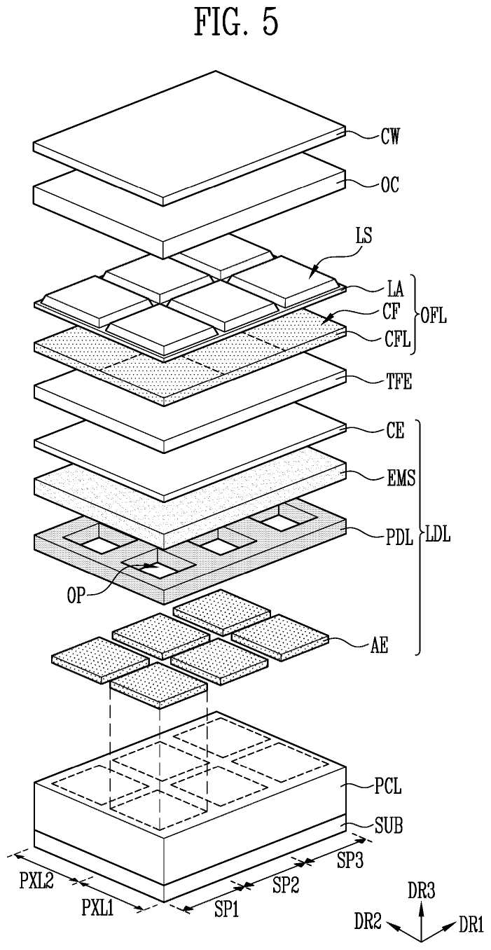

FIG. 5 is an exploded perspective view illustrating a portion of the display panel of FIG. 4. In FIG. 5, for clear and concise description, a portion of the display panel DP corresponding to two pixels PXL1 and PXL2 among the pixels PXL of FIG. 4 is schematically shown. A portion of the display panel DP corresponding to remaining pixels may be similarly configured.

Referring to FIGS. 4 and 5, each of the first and second pixels PXL1 and PXL2 may include first to third sub-pixels SP1 to SP3. However, embodiments are not limited thereto. For example, each of the first and second pixels PXL1 and PXL2 may include four sub-pixels or two sub-pixels.

In FIG. 5, the first to third sub-pixels SP1 to SP3 have quadrangle shapes when viewed from a third direction DR3 crossing the first and second directions DR1 and DR2, and have sizes equal to each other. However, embodiments are not limited thereto. According to one or more embodiments, the first to third sub-pixels SP1 to SP3 may be modified to have various shapes.

The display panel DP may include the substrate SUB, a pixel circuit layer PCL, a light-emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL may be located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include copper, but embodiments are not limited thereto.

The circuit elements may include the sub-pixel circuit SPC of each of the first to third sub-pixels SP1 to SP3. The sub-pixel circuit SPC may include transistors and one or more capacitors. Each transistor may include a semiconductor portion including a source area, a drain area, and a channel area, and a gate electrode overlapping the semiconductor portion. In embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1 to SP3, for example, a gate line, an emission control line, a data line, and the like. The lines may further include a line connected to the first power voltage node VDDN of FIG. 2. The lines may further include a line connected to the second power voltage node VSSN of FIG. 2.

The light-emitting element layer LDL may include the anode electrodes AE, a pixel-defining layer PDL, a light-emitting structure EMS, and the cathode electrode CE.

The anode electrodes AE may be located on the pixel circuit layer PCL. The anode electrodes AE may be electrically connected to the circuit elements of the pixel circuit layer PCL. The anode electrodes AE may include an opaque conductive material capable of reflecting light, but embodiments are not limited thereto.

The pixel-defining layer PDL may be located on the anode electrodes AE. The pixel-defining layer PDL may include an opening OP exposing a portion of each of the anode electrodes AE. The opening OP of the pixel-defining layer PDL may be understood as emission areas corresponding to the first to third sub-pixels SP1 to SP3, respectively.

In embodiments, the pixel-defining layer PDL may include an inorganic material. In this case, the pixel-defining layer PDL may include a plurality of stacked inorganic layers. For example, the pixel-defining layer PDL may include silicon oxide SiOx and/or silicon nitride SiNx. In other embodiments, the pixel-defining layer PDL may include an organic material. However, a material of the pixel-defining layer PDL is not limited thereto.

The light-emitting structure EMS may be located on the anode electrodes AE exposed by the opening OP of the pixel-defining layer PDL. The light-emitting structure EMS may include a light-emitting layer configured to generate light, an electron transport layer configured to transport an electron, a hole transport layer configured to transport a hole, and the like.

In embodiments, the light-emitting structure EMS may fill the opening OP of the pixel-defining layer PDL, and may be entirely located on the pixel-defining layer PDL. The light-emitting structure EMS may extend across the first to third sub-pixels SP1 to SP3. In this case, at least a portion of layers in the light-emitting structure EMS may be separated (disconnected) or bent at boundaries between the first to third sub-pixels SP1 to SP3. However, embodiments are not limited thereto. For example, portions of the light-emitting structure EMS corresponding to the first to third sub-pixels SP1 to SP3 may be separated from each other, and each of the separated light-emitting structures EMS may be located in the opening OP of the pixel-defining layer PDL.

The cathode electrode CE may be located on the light-emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light-emitting structure EMS. The cathode electrode CE may be formed of a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or a mixture thereof. However, a material of the cathode electrode CE is not limited thereto.

It may be understood that one of the anode electrodes AE, a portion of the light-emitting structure EMS overlapping it, and a portion of the cathode electrode CE overlapping it configure one light-emitting element LD (refer to FIG. 2). Each of the light-emitting elements of the first to third sub-pixels SP1 to SP3 may include one anode electrode AE, a portion of the light-emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light-emitting layer of the light-emitting structure EMS to form excitons, and when the excitons transits from an excited state to a ground state, light may be generated. A luminance of light may be determined according to an amount of a current flowing through the light-emitting layer. According to a configuration of the light-emitting layer, a wavelength range of the generated light may be determined.

The encapsulation layer TFE may be located on the cathode electrode CE. The encapsulation layer TFE may cover the light-emitting element layer LDL and/or the pixel circuit layer PCL. The encapsulation layer TFE may be configured to reduce or prevent oxygen, moisture, and/or the like permeating to the light-emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. The organic layer may include an organic insulating material, such as acrylic resin, epoxy resin, phenol resin, polyamide resin, polyimide resin, unsaturated polyester resin, polyphenylenether resin, polyphenylenesulfide resin, or benzocyclobutene (BCB). However, materials of the organic layer and the inorganic layer of the encapsulation layer TFE are not limited thereto.

To improve an encapsulation efficiency of the encapsulation layer TFE, the encapsulation layer TFE may further include a thin film including aluminum oxide (AlOx). The thin film including the aluminum oxide may be positioned on an upper surface of the encapsulation layer TFE facing the optical functional layer OFL and/or a lower surface of the encapsulating layer TFE facing the light-emitting element layer LDL.

The thin film including the aluminum oxide may be formed through atomic layer deposition (ALD) method. However, embodiments are not limited thereto. The encapsulation layer TFE may further include a thin film formed of at least one of various materials suitable for improving the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured to filter the light emitted from the light-emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light-emitting structure EMS of each sub-pixel, at least a portion of the color filters CF may be omitted.

The lens array LA may be located on the color filter layer CFL. The lens array LA may include lenses LS respectively corresponding to the first to third sub-pixels SP1 to SP3. Each of the lenses LS may improve a light output efficiency by outputting the light emitted from the light-emitting structure EMS to an intended path. The lens array LA may have a relatively high refractive index. For example, the lens array LA may have a refractive index higher than that of the overcoat layer OC. In embodiments, the lenses LS may include an organic material. In embodiments, the lenses LS may include an acrylic material. However, a material of the lenses LS is not limited thereto.

In embodiments, compared to the opening OP of the pixel-defining layer PDL, at least a portion of the color filters CF of the color filter layer CFL and at least a portion of the lenses LS of the lens array LA may be shifted in a direction substantially parallel to the plane defined by the first and second directions DR1 and DR2. For example, in a central area of the display area DA, a center of the color filter and a center of the lens may be aligned with or overlap with a center of the opening OP of the corresponding pixel-defining layer PDL when viewed in the third direction DR3. For example, in the central area of the display area DA, the opening OP of the pixel-defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a plane direction from the center of the opening OP of the corresponding pixel-defining layer PDL when viewed in the third direction DR3. For example, in the area adjacent to the non-display area NDA in the display area DA, the opening OP of the pixel-defining layer PDL may partially overlap the corresponding color filter of the color filter layer CFL, and the corresponding lens of the lens array LA. Accordingly, at a center of the display area DA, the light emitted from the light-emitting structure EMS may be efficiently output in a normal direction of a display surface. At an outskirt of the display area DA, the light emitted from the light-emitting structure EMS may be efficiently output in a direction inclined by an angle (e.g., predetermined angle) with respect to the normal direction of the display surface.

The overcoat layer OC may be located on the lens array LA. The overcoat layer OC may cover the optical functional layer OFL, the encapsulation layer TFE, the light-emitting structure EMS, and/or the pixel circuit layer PCL. The overcoat layer OC may include various materials suitable for protecting layers thereunder from a foreign substance, such as dust or moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index lower than that of the lens array LA.

The cover window CW may be located on the overcoat layer OC. The cover window CW may be configured to protect layers thereunder. The cover window CW may have a refractive index that is higher than that of the overcoat layer OC. The cover window CW may include glass, but embodiments are not limited thereto. For example, the cover window CW may be an encapsulation glass configured to protect components located thereunder. In other embodiments, the cover window CW may be omitted.

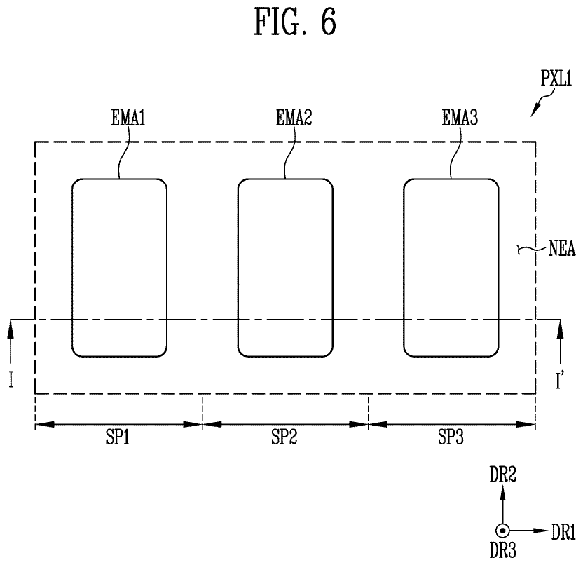

FIG. 6 is a plan view illustrating one or more embodiments of one of the pixels of FIG. 5. In FIG. 6, for clear and concise description, the first pixel PXL1 of the 1 first and second pixels PXL1 and PXL2 of FIG. 5 may be schematically shown. The remaining pixels may be configured similarly to the first pixel PXL1.

Referring to FIGS. 5 and 6, the first pixel PXL1 may include the first to third sub-pixels SP1 to SP3 arranged in the first direction DR1.

The first sub-pixel SP1 may include a first emission area EMA1, and a non-emission area NEA around the first emission area EMA1. The second sub-pixel SP2 may include a second emission area EMA2, and a non-emission area NEA around the second emission area EMA2. The third sub-pixel SP3 may include a third emission area EMA3, and a non-emission area NEA around the third emission area EMA3.

The first emission area EMA1 may be an area where light is emitted from a portion of the light-emitting structure EMS (refer to FIG. 5) corresponding to the first sub-pixel SP1. The second emission area EMA2 may be an area where light is emitted from a portion of the light-emitting structure EMS corresponding to the second sub-pixel SP2. The third emission area EMA3 may be an area where light is emitted from a portion of the light-emitting structure EMS corresponding to the third sub-pixel SP3. As described with reference to FIG. 5, each emission area may be understood as the opening OP of the pixel-defining layer PDL corresponding to each of the first to third sub-pixels SP1 to SP3.

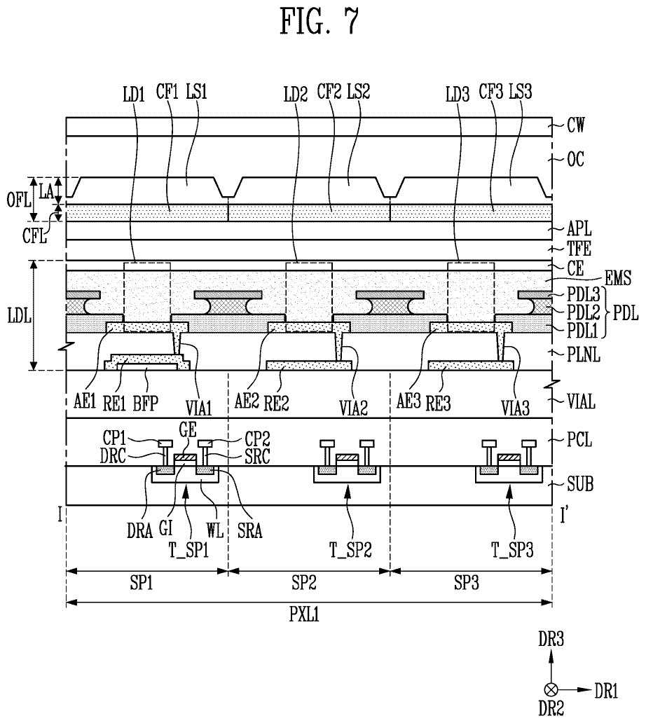

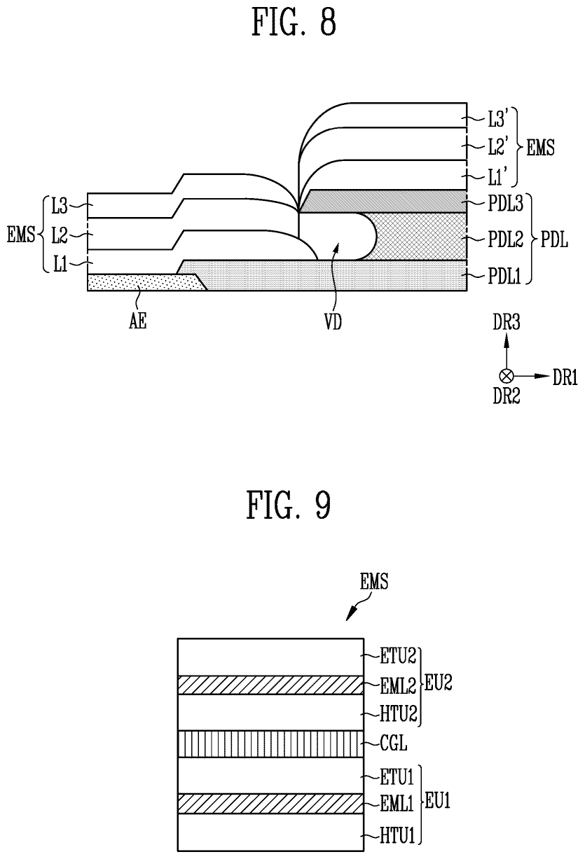

FIG. 7 is a cross-sectional view illustrating one or more embodiments taken along the line I-I′ of FIG. 6. FIG. 8 is a cross-sectional view illustrating one or more embodiments of a light-emitting structure of FIG. 7.

Referring to FIGS. 7 and 8, the substrate SUB and the pixel circuit layer PCL located on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be located on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (refer to FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 7, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in the substrate SUB, and the source area SRA and the drain area DRA may be located to be spaced apart from each other in the well WL. An area between the source area SRA and the drain area DRA in the well WL may be defined as a channel area.

The gate electrode GE may overlap the channel area between the source area SRA and the drain area DRA, and may be located in the pixel circuit layer PCL. The gate electrode GE may be spaced apart from the well WL or the channel area by an insulating material, such as a gate insulating layer GI. The gate electrode GE may include a conductive material.

A plurality of layers included in the pixel circuit layer PCL may include insulating layers, and conductive patterns located between the insulating layers, and the conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL may be located on the pixel circuit layer PCL. The via layer VIAL may cover the pixel circuit layer PCL, and may have a generally flat surface. The via layer VIAL may be configured to planarize steps on the pixel circuit layer PCL. The via layer VIAL may include at least one of silicon oxide (SiOx), silicon nitride (SiNx), or silicon carbon nitride (SiCN), but embodiments are not limited thereto.

The light-emitting element layer LDL may be located on the via layer VIAL. The light-emitting element layer LDL may include first to third reflective electrodes RE1 to RE3, a planarization layer PLNL, first to third anode electrodes AE1 to AE3, the pixel-defining layer PDL, the light-emitting structure EMS, and the cathode electrode CE.

On the via layer VIAL, the first to third reflective electrodes RE1 to RE3 may be located in the first to third sub-pixels SP1 to SP3, respectively. Each of the first to third reflective electrodes RE1 to RE3 may be electrically connected to the circuit 1 element located in the pixel circuit layer PCL through a via passing through the via layer VIAL.

The first to third reflective electrodes RE1 to RE3 may function as a full mirror reflecting the light emitted from the light-emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from them, but embodiments are not limited thereto.

In embodiments, a connection electrode may be located under each of the first to third reflective electrodes RE1 to RE3. The connection electrode may improve an electrical connection characteristic between a corresponding reflective electrode and the circuit element of the pixel circuit layer PCL. The connection electrode may have a multiple layer structure. The multiple layer structure may include titanium (Ti), titanium nitride (TiN), tantalum nitride (TaN), and the like, but embodiments are not limited thereto. In embodiments, a corresponding reflective electrode may be positioned between the multiple layers of the connection electrode.

A buffer pattern BFP may be located under at least one of the first to third reflective electrodes RE1 to RE3. The buffer pattern BFP may include an inorganic material, such as silicon carbon nitride, but embodiments are not limited thereto. By using the buffer pattern BFP, a height of the third direction DR3 of the corresponding reflective electrode may be adjusted. For example, the buffer pattern BFP may be located between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. The light emitted from the light-emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light-emitting layer of the corresponding light-emitting structure EMS.

The first sub-pixel SP1 may have a resonance distance that is less than that of another sub-pixel due to the buffer pattern BFP. The resonance distance adjusted as described above may allow light of a corresponding wavelength range (for example, red color) to be effectively and efficiently amplified. Accordingly, the first sub-pixel SP1 may effectively and efficiently output light of a corresponding wavelength range.

In FIG. 7, the buffer pattern BFP is provided to the first sub-pixel SP1, and is not provided to the second and third sub-pixels SP2 and SP3, but embodiments are not limited thereto. The buffer pattern may also be provided in at least one of the second or third sub-pixels SP2 or SP3 to adjust a resonance distance of at least one of the second or third sub-pixels SP2 or SP3. For example, the first to third sub-pixels SP1 to SP3 may correspond to red, green, and blue, respectively, and a distance between the first reflective electrode RE1 and the cathode electrode CE may be less than a distance between the second reflective electrode RE2 and the cathode electrode CE. The distance between the second reflective electrode RE2 and the cathode electrode CE may be less than a distance between the third reflective electrode RE3 and the cathode electrode CE.

To flatten steps between the first to third reflective electrodes RE1 to RE3, the planarization layer PLNL may be located on the via layer VIAL and the first to third reflective electrodes RE1 to RE3. The planarization layer PLNL may generally cover the first to third reflective electrodes RE1 to RE3 and the via layer VIAL, and may have a flat surface. In embodiments, the planarization layer PLNL may be omitted.

On the planarization layer PLNL, the first to third anode electrodes AE1 to AE3 may respectively overlap the first to third reflective electrodes RE1 to RE3. The first to third anode electrodes AE1 to AE3 may have shapes similar to those of the first to third emission areas EMA1 to EMA3 of FIG. 6 when viewed in the third direction DR3. The first to third anode electrodes AE1 to AE3 may be connected to the first to third reflective electrodes RE1 to RE3, respectively. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

The first to third anode electrodes AE1 to AE3 may include at least one of transparent conductive materials, such as indium tin oxide (ITO), indium zinc oxide (IZO), zinc oxide (ZnOₓ), indium gallium zinc oxide (IGZO), or indium tin zinc oxide (ITZO). However, a material of the first to third anode electrodes AE1 to AE3 is not limited thereto. For example, the first to third anode electrodes AE1 to AE3 may include titanium nitride.

In embodiments, insulating layers for adjusting a height of one or more of the first to third anode electrodes AE1 to AE3 may be further provided. The insulating layers may be located between one or more of the first to third anode electrodes AE1 to AE3 and corresponding reflective electrodes. In this case, the planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be less than a distance between the second anode electrode AE2 and the cathode electrode CE. The distance between the second anode electrode AE2 and the 1 cathode electrode CE may be less than a distance between the third anode electrode AE3 and the cathode electrode CE.

The pixel-defining layer PDL may be located on portions of the first to third anode electrodes AE1 to AE3 and the planarization layer PLNL. The pixel-defining layer PDL may define the opening OP exposing a portion of each of the first to third anode electrodes AE1 to AE3. The opening OP of the pixel-defining layer PDL may define the emission area of each of the first to third sub-pixels SP1 to SP3. As described above, the pixel-defining layer PDL may be located in the non-emission area NEA of FIG. 6 to define the first to third emission areas EMA1 to EMA3 of FIG. 6.

The pixel-defining layer PDL may include first to third pixel-defining layers PDL1, PDL2, and PDL3. Each of the first to third pixel-defining layers PDL1, PDL2, and PDL3 may include at least one of silicon oxide (SiOx) or silicon nitride (SiNx), but is not necessarily limited thereto.

The first pixel-defining layer PDL1 may be located on the anode electrode AE. The first pixel-defining layer PDL1 may be directly located on the anode electrode AE (e.g., on edges of the anode electrode AE).

The second pixel-defining layer PDL2 may be located on the first pixel-defining layer PDL1. The second pixel-defining layer PDL2 may be directly located on the first pixel-defining layer PDL1. A width in the first direction DR1 of the second pixel-defining layer PDL2 may be less than a width in the first direction DR1 of the first pixel-defining layer PDL1. A width in the first direction DR1 of an opening of the second pixel-defining layer PDL2 may be greater than a width in the first direction DR1 of an opening of the first pixel-defining layer PDL1.

The third pixel-defining layer PDL3 may be located on the second pixel-defining layer PDL2. The third pixel-defining layer PDL3 may be directly located on the second pixel-defining layer PDL2. A width in the first direction DR1 of the third pixel-defining layer PDL3 may be greater than the width in the first direction DR1 of the second pixel-defining layer PDL2. A width in the first direction DR1 of an opening of the third pixel-defining layer PDL3 may be less than the width in the first direction DR1 of the opening of the second pixel-defining layer PDL2.

As shown in FIG. 8, a void VD may be formed between the first pixel-defining layer PDL1 and the third pixel-defining layer PDL3. For example, a lower surface of the void VD may be defined by the first pixel-defining layer PDL1. A side surface of the void VD may be defined by the second pixel-defining layer PDL2. An upper surface of the void VD may be defined by the third pixel-defining layer PDL3.

The void VD may cause a discontinuity to be formed in the light-emitting structure EMS between the first to third sub-pixels SP1 to SP3. A portion of a plurality of layers stacked in the light-emitting structure EMS may be disconnected or bent due to the void VD. For example, at least one charge generation layer included in the light-emitting structure EMS may be disconnected at the void VD. As described above, portions of the light-emitting structure EMS included in the first to third sub-pixels SP1 to SP3 may be at least partially separated due to the void VD. Accordingly, when the display panel DP is operated, a current flowing out from each of the first to third sub-pixels SP1 to SP3 to sub-pixel adjacent thereto through the layers included in the light-emitting structure EMS may be reduced. Therefore, first to third light-emitting elements LD1 to LD3 may operate with relatively high reliability.

The light-emitting structure EMS may be located on the anode electrode AE and the pixel-defining layer PDL. The light-emitting structure EMS may be located on the anode electrodes AE exposed by the pixel-defining layer PDL. The light-emitting structure EMS may be located entirely across the first to third sub-pixels SP1 to SP3.

The light-emitting structure EMS may have a structure in which a plurality of layers are stacked. For example, and as shown in FIG. 8, the light-emitting structure EMS may include first to third layers L1, L1′, L2, L2′, L3, and L3′ sequentially stacked on the anode electrode AE.

A portion or all of the plurality of layers included in the light-emitting structure EMS may be separated or bent between the first to third sub-pixels SP1 to SP3 by the void VD. For example, the light-emitting structure EMS may include the first areas L1, L2, and L3 and second areas L1′, L2′, and L3′ separated by the void VD. The first areas L1, L2, and L3 may be located on the first pixel-defining layer PDL1, and the second areas L1′, L2′, and L3 may be located on the third pixel-defining layer PDL3.

In one or more embodiments, a thickness of the third direction DR3 of the first area L1 and/or the second area L1′ of the first layer may become thinner toward their respective edges. That is, the first area L1 and/or the second area L1′ of the first layer may include a shadow area. The first area L1 of the first layer may overlap the third pixel-defining layer PDL3 in the third direction DR3. That is, the shadow area of the first area L1 of the first layer may overlap the third pixel-defining layer PDL3 in the third direction DR3.

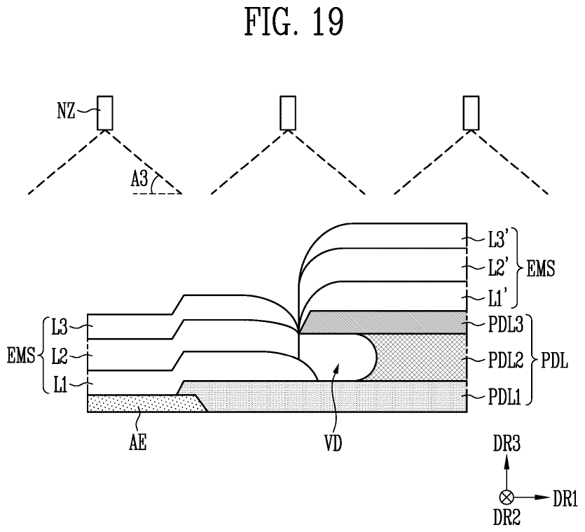

A thickness of the third direction DR3 of the first area L2 and/or the second area L2′ of the second layer may be substantially uniform. For example, in a step of forming the second layers L2 and L2′, the thickness of the third direction DR3 of the second layers L2 and L2′ may be formed to be uniform by improving a shadow effect by increasing an incidence angle of deposition material particles. For example, the second layers L2 and L2′ may correspond to a light-emitting layer or a hole transport layer, but are not necessarily limited thereto. As described above, a generation of a carrier that bypasses without contributing to light emission may be reduced or minimized by reducing or minimizing a thickness dispersion of some layers of the light-emitting structure EMS, for example, the second layers L2 and L2′, thereby improving a light emission efficiency. A detailed description of this is be provided later with reference to FIGS. 16 to 19. As the shadow area is decreased in the first area L2 of the second layer, a width in the first direction DR1 of the first area L2 of the second layer may be less than a width in the first direction DR1 of the first area L1 of the first layer. The first area L2 of the second layer may not overlap the third pixel-defining layer PDL3 in the third direction DR3. An edge of the first area L2 of the second layer may be aligned with an edge of the third pixel-defining layer PDL3 in the third direction DR3.

A thickness of the third direction DR3 of the first area L3 and/or the second area L3′ of the third layer may become thinner toward their respective edges. That is, the first area L3 and/or the second area L3′ of the third layer may include a shadow area. The first area L3 of the third layer may not overlap the third pixel-defining layer PDL3 in the third direction DR3. For example, an edge of the first area L3 of the third layer may be aligned with an edge of the third pixel-defining layer PDL3 in the third direction DR3.

As can be seen in FIG. 7, the cathode electrode CE may be located on the light-emitting structure EMS. The cathode electrode CE may be commonly provided to the first to third sub-pixels SP1 to SP3. The cathode electrode CE may function as a half mirror that partially transmits and partially reflects light emitted from the light-emitting structure EMS. The cathode electrode CE may be commonly provided to the first to third sub-pixels SP1 to SP3.

The first anode electrode AE1, a portion of the light-emitting structure EMS overlapping the first anode electrode AE1, and a portion of the cathode electrode CE overlapping the first anode electrode AE1 may configure the first light-emitting element LD1. The second anode electrode AE2, a portion of the light-emitting structure EMS overlapping the second anode electrode AE2, and a portion of the cathode electrode CE overlapping the second anode electrode AE2 may configure the second light-emitting element LD2. The third anode electrode AE3, a portion of the light-emitting structure EMS overlapping the third anode electrode AE3, and a portion of the cathode electrode CE overlapping the third anode electrode AE3 may configure the third light-emitting element LD3.

The encapsulation layer TFE may be located on the cathode electrode CE. The encapsulation layer TFE may reduce or prevent oxygen, moisture, and/or the like permeating to the light-emitting element layer LDL.

The optical functional layer OFL may be located on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

In embodiments, the first to third color filters CF1 to CF3 may partially overlap between the first to third sub-pixels SP1 to SP3. In other embodiments, the first to third color filters CF1 to CF3 may be spaced apart from each other, and a black matrix may be provided between the first to third color filters CF1 to CF3.

The lens array LA may be located on the color filter layer CFL. The lens array LA may include first to third lenses LS1 to LS3 respectively corresponding to the first to third sub-pixels SP1 to SP3. Each of the first to third lenses LS1 to LS3 may improve light output efficiency by outputting light emitted from the first to third light-emitting elements LD1 to LD3 to an intended path.

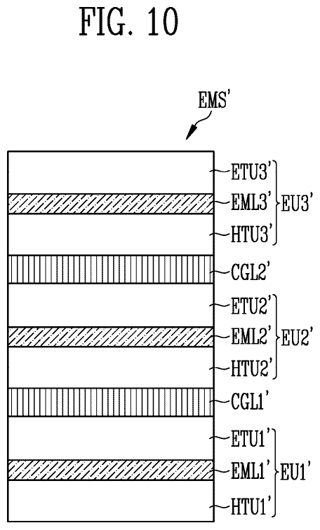

FIG. 9 is a cross-sectional view illustrating one or more embodiments of a light-emitting structure included in one of the first to third light-emitting elements of FIG. 7.

Referring to FIG. 9, the light-emitting structure EMS may have a tandem structure in which first and second light-emitting units EU1 and EU2 are stacked. The light-emitting structure EMS may be configured substantially equally in each of the first to third light-emitting elements LD1 to LD3 of FIG. 7.

Each of the first and second light-emitting units EU1 and EU2 may include at least one light-emitting layer that generates light according to an applied current. The first light-emitting unit EU1 may include a first light-emitting layer EML1, a first electron transport unit ETU1, and a first hole transport unit HTU1. The first light-emitting layer EML1 may be located between the first electron transport unit ETU1 and the first hole transport unit HTU1.

The second light-emitting unit EU2 may include a second light-emitting layer EML2, a second electron transport unit ETU2, and a second hole transport unit HTU2. The second light-emitting layer EML2 may be located between the second electron transport unit ETU2 and the second hole transport unit HTU2.

Each of the first and second hole transport units HTU1 and HTU2 may include at least one of a hole injection layer or a hole transport layer, and may further include a hole buffer layer, an electron-blocking layer, and the like, if suitable. The first and second hole transport units HTU1 and HTU2 may have configurations equal to each other or different from each other.

Each of the first and second electron transport units ETU1 and ETU2 may include at least one of an electron injection layer or an electron transport layer, and may further include an electron buffer layer, a hole-blocking layer, and the like, if suitable. The first and second electron transport units ETU1 and ETU2 may have configurations equal to each other or different from each other.

A connection layer, which may be provided in a form of a charge generation layer CGL, may be located between the first light-emitting unit EU1 and the second light-emitting unit EU2 to connect the first light-emitting unit EU1 and the second light-emitting unit EU2 to each other. In embodiments, the charge generation layer CGL may have a stack structure of a p dopant layer and an n dopant layer. For example, the p dopant layer may include a p-type dopant, such as HAT-CN, TCNQ, and NDP-9, and the n dopant layer may include an alkali metal, an alkaline earth metal, a lanthanide metal, or a combination thereof. However, embodiments are not limited thereto.

In embodiments, the first light-emitting layer EML1 and the second light-emitting layer EML2 may generate light of different colors. Light emitted from each of the first light-emitting layer EML1 and the second light-emitting layer EML2 may be mixed and viewed as white light. For example, the first light-emitting layer EML1 may generate blue light, and the second light-emitting layer EML2 may generate yellow light. In embodiments, the second light-emitting layer EML2 may include a structure in which a first sub light-emitting layer configured to generate red light and a second sub light-emitting layer configured to generate green light are stacked. The red light and the green light may be mixed, and thus the yellow light may be provided. In this case, an intermediate layer configured to perform a function of transporting holes and/or blocking transport of electrons may be further located between the first and second sub light-emitting layers. In other embodiments, the first light-emitting layer EML1 and the second light-emitting layer EML2 may generate light of the same color.

The light-emitting structure EMS may be formed through a method, such as vacuum deposition and inkjet printing, but embodiments are not limited thereto.

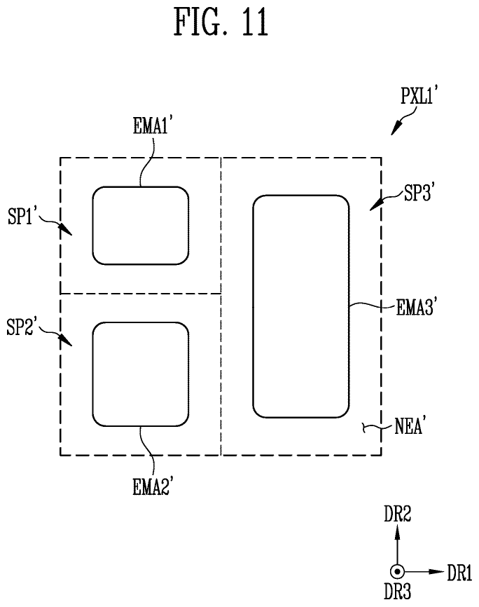

FIG. 10 is a cross-sectional view illustrating one or more other embodiments of the light-emitting structure included in one of the first to third light-emitting elements of FIG. 7.

Referring to FIG. 10, the light-emitting structure EMS' may have a tandem structure in which first to third light-emitting units EU1′ to EU3′ are stacked. The light-emitting structure EMS' may be configured substantially equally in each of the first to third light-emitting elements LD1 to LD3 of FIG. 7.

Each of the first to third light-emitting units EU1′ to EU3′ may include a light-emitting layer that generates light according to an applied current. The first light-emitting unit EU1′ may include a first light-emitting layer EML1′, a first electron transport unit ETU1′, and a first hole transport unit HTU1′. The first light-emitting layer EML1′ may be located between the first electron transport unit ETU1′ and the first hole transport unit HTU1′.

The second light-emitting unit EU2′ may include a second light-emitting layer EML2′, a second electron transport unit ETU2′, and a second hole transport unit HTU2′. The second light-emitting layer EML2′ may be located between the second electron transport unit ETU2′ and the second hole transport unit HTU2′.

The third light-emitting unit EU3′ may include a third light-emitting layer EML3′, a third electron transport unit ETU3′, and a third hole transport unit HTU3′. The third light-emitting layer EML3′ may be located between the third electron transport unit ETU3′ and the third hole transport unit HTU3′.

Each of the first to third hole transport units HTU1′ to HTU3′ may include at least one of a hole injection layer or a hole transport layer, and may further include a hole buffer layer, an electron-blocking layer, and the like, if suitable. The first to third hole transport units HTU1′ to HTU3′ may have configurations equal to each other or different from each other.

Each of the first to third electron transport units ETU1′ to ETU3′ may include at least one of an electron injection layer or an electron transport layer, and may further include an electron buffer layer, a hole-blocking layer, and the like, if suitable. The first to third electron transport units ETU1′ to ETU3′ may have configurations equal to each other or different from each other.

A first charge generation layer CGL1′ may be located between the first light-emitting unit EU1′ and the second light-emitting unit EU2′. A second charge generation layer CGL2′ may be located between the second light-emitting unit EU2′ and the third light-emitting unit EU3′.

In embodiments, the first to third light-emitting layers EML1′ to EML3′ may generate light of different respective colors. Light emitted from each of the first to third light-emitting layers EML1′ to EML3′ may be mixed and may be viewed as white light. For example, the first emitting layer EML1′ may generate light of a blue color, the second emitting layer EML2′ may generate light of a green color, and the third emitting layer EML3′ may generate light of a red color. In other embodiments, two or more of the first to third light-emitting layers EML1′ to EML3′ may generate light of the same color.

Differently from that shown in FIGS. 9 and 10, the light-emitting structure EMS of FIG. 7 may include one light-emitting unit in each of the first to third light-emitting elements LD1 to LD3. At this time, the light-emitting unit included in each of the first to third light-emitting elements LD1 to LD3 may be configured to emit light of different colors. For example, the light-emitting unit of the first light-emitting element LD1 may emit the light of the red color, the light-emitting unit of the second light-emitting element LD2 may emit the light of the green light, and the light-emitting unit of the third light-emitting element LD3 may emit the light of the blue color. In this case, the light-emitting units of the first to third sub-pixels SP1 to SP3 may be separated from each other, and each of them may be located in an opening OP of the pixel-defining layer PDL. In this case, at least a portion of the color filters CF1 to CF3 may be omitted.

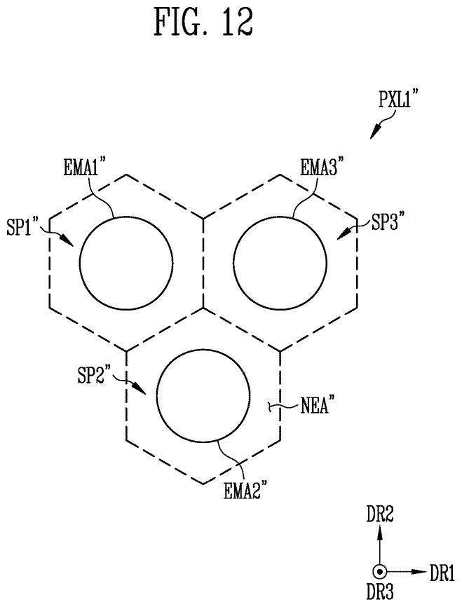

FIG. 11 is a plan view illustrating one or more other embodiments of one of the pixels of FIG. 5.

Referring to FIG. 11, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area that is greater than that of the first sub-pixel SP1′, and the third sub-pixel SP3′ may have an area that is greater than that of the second sub-pixel SP2′. Accordingly, the second emission area EMA2′ may have an area that is greater than the first emission area EMA1′, and the third emission area EMA3′ may have an area that is greater than that of the second emission area EMA2′. However, embodiments are not limited thereto. For example, the first and second sub-pixels SP1′ and SP2′ may have substantially the same area, and the third sub-pixel SP3′ may have an area that is greater than that of each of the first and second sub-pixels SP1′ and SP2′. As described above, the areas of the first to third sub-pixels SP1′ to SP3′ may vary according to embodiments.

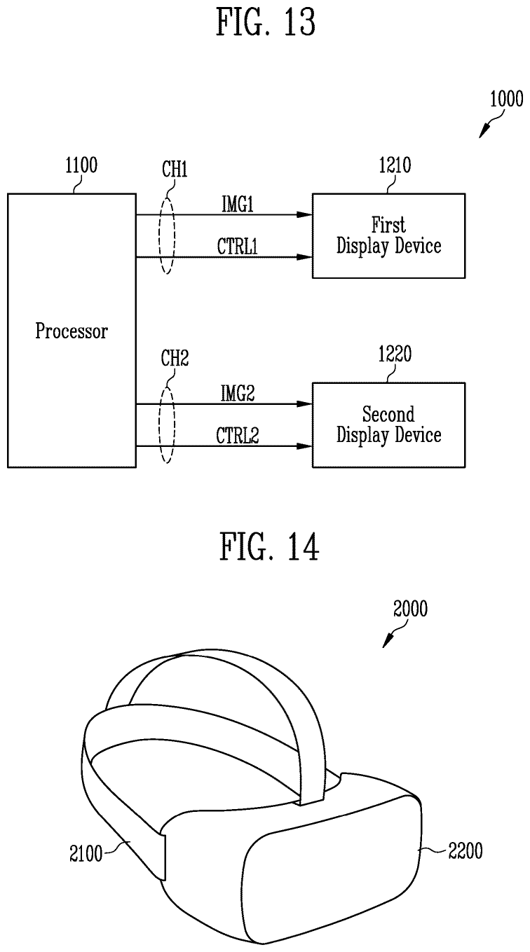

FIG. 12 is a plan view illustrating still one or more other embodiments of one of the pixels of FIG. 5.

Referring to FIG. 12, a first sub-pixel SP1″ may include a first emission area EMA1″ and a non-emission area NEA″ around the first emission area EMA1″. A second sub-pixel SP2″ may include a second emission area EMA2″ and a non-emission area NEA″ around the second emission area EMA2″. A third sub-pixel SP3″ may include a third emission area EMA3″ and a non-emission area NEA″ around the third emission area EMA3″.

The first to third sub-pixels SP1″ to SP3″ may have polygonal shapes when viewed in the third direction DR3. For example, shapes of the first to third sub-pixels SP1″ to SP3″ may be hexagonal shapes.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be located in a direction inclined by an acute angle based on the second direction DR2 (or a diagonal direction) with respect to the first sub-pixel SP1″.

An arrangement of the sub-pixels shown in FIGS. 6, 11, and 12 is only an example, and embodiments are not limited thereto. Each pixel may include two or more sub-pixels SP, the sub-pixels SP may be arranged in various methods, the respective sub-pixels may have various shapes, and respective emission areas EMA1, EMA2, and EMA3 thereof may also have various shapes.

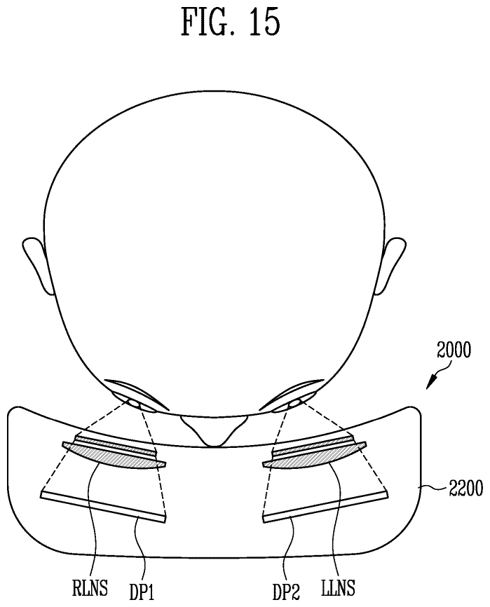

FIG. 13 is a block diagram illustrating one or more embodiments of a display system.

Referring to FIG. 13, the display system 1000 may include a processor 1100 and one or more display devices 1210 and 1220.

The processor 1100 may perform various tasks and calculations. In embodiments, the processor 1100 may include an application processor, a graphic processor, a microprocessor, a central processing unit (CPU), and the like. The processor 1100 may be connected to other components of the display system 1000 through a bus system and may control the other components.

In FIG. 13, the display system 1000 may be shown to include the first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra-mobile personal computer (UMPC). In addition, the display system 1000 may include at least one of a head-mounted display (HMD) device, a virtual reality (VR) device, a mixed reality (MR) device, or an augmented reality (AR) device.

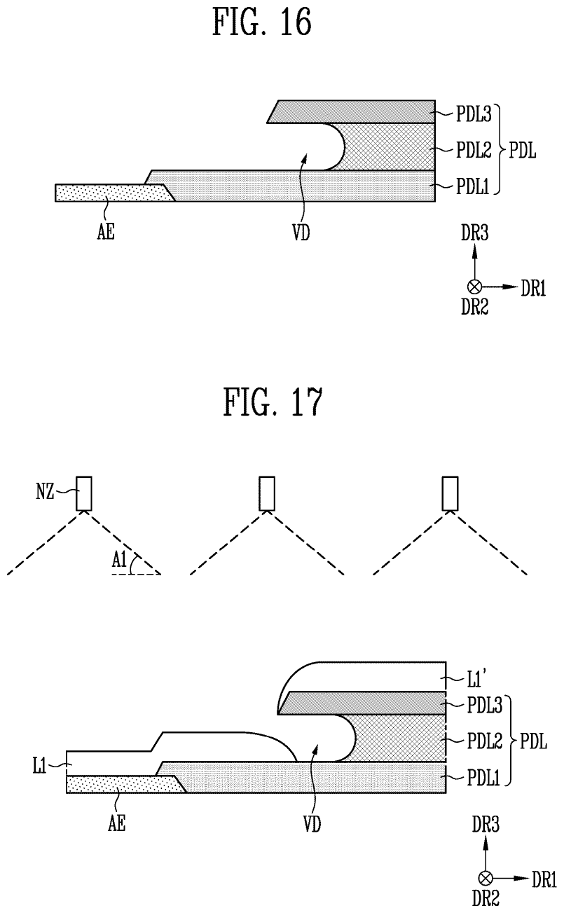

FIG. 14 is a perspective view illustrating an application example of the display system of FIG. 13.

Referring to FIG. 14, the display system 1000 of FIG. 13 may be applied to a head-mounted display device 2000. The head-mounted display device 2000 may be a wearable electronic device that may be worn on a user's head.

The head-mounted display device 2000 may include a head mount band 2100 and a display device receiving case 2200. The head mount band 2100 may be connected to the display device receiving case 2200. The head mount band 2100 may include a horizontal band and/or a vertical band for fixing the head-mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device receiving case 2200 may receive the first and second display devices 1210 and 1220 of FIG. 13. The display device receiving case 2200 may further receive the processor 1100 of FIG. 13.

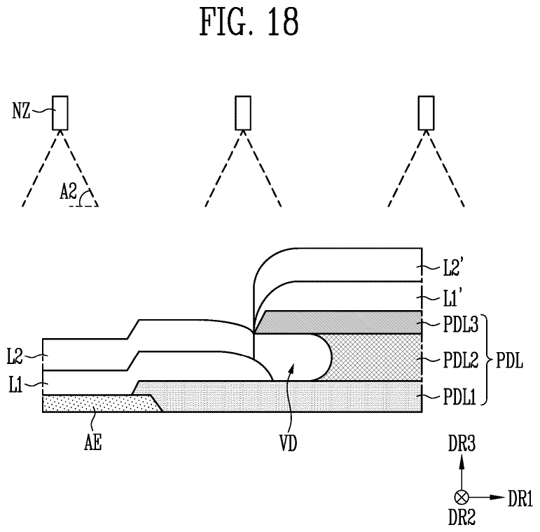

FIG. 15 is a diagram illustrating the head-mounted display device worn by a user of FIG. 14.

Referring to FIG. 15, in the head-mounted display device 2000, a first display panel DP1 of the first display device 1210 and a second display panel DP2 of the second display device 1220 are located. The head-mounted display device 2000 may further include one or more lenses LLNS and RLNS.

Within the display device receiving case 2200, the right eye lens RLNS may be located between the first display panel DP1 and a user's right eye. Within the display device receiving case 2200, the left eye lens LLNS may be located between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

Next, a method of manufacturing the display device, as described above, is described.

FIGS. 16 to 19 are cross-sectional views for each process step of a method of manufacturing a display device according to one or more embodiments. FIGS. 16 to 19 are cross-sectional views illustrating a method of manufacturing the display device of FIGS. 1 to 15, and are shown briefly and detailed symbols are omitted for convenience of description.

Referring to FIG. 16, first, the anode electrode AE is formed, and the first to third pixel-defining layers PDL1, PDL2, and PDL3 are sequentially formed on the anode electrode AE (e.g., above the anode electrode AE, or on a portion of the anode electrode AE). The width in the first direction DR1 of the second pixel-defining layer

PDL2 may be formed to be less than the width in the first direction DR1 of the first pixel-defining layer PDL1. The width in the first direction DR1 of the third pixel-defining layer PDL3 may be formed to be greater than the width in the first direction DR1 of the second pixel-defining layer PDL2. Accordingly, the void VD may be formed between the first pixel-defining layer PDL1 and the third pixel-defining layer PDL3. For example, the lower surface of the void VD may be defined by the first pixel-defining layer PDL1. The side surface of the void VD may be defined by the second pixel-defining layer PDL2. The upper surface of the void VD may be defined by the third pixel-defining layer PDL3. Each of the first to third pixel-defining layers PDL1, PDL2, and PDL3 may be formed of at least one of silicon oxide (SiOx) or silicon nitride (SiNx), but is not necessarily limited thereto.

Referring to FIG. 17, the first layers L1 and L1′ of the light-emitting structure EMS are formed on the anode electrode AE and the pixel-defining layer PDL. The first layers L1 and L1′ may be separated into the first area L1 and the second area L1′ by an undercut structure or the void VD of the pixel-defining layer PDL. The first area L1 of the first layer may be formed on the first pixel-defining layer PDL1. The second area L1′ of the first layer may be formed on the third pixel-defining layer PDL3.

The first layers L1 and L1′ may be formed through a deposition process. For example, a material of the first layers L1 and L1′ may be vaporized at a deposition source and sprayed from a nozzle NZ to be deposited. Deposition material particles of the first layer L1 and L1′ may be sprayed from the nozzle NZ at a first incidence angle A1. In one or more embodiments, the first incidence angle A1 may be about 50° or more, but is not necessarily limited thereto. As described above, when the deposition material particles are deposited at the first incidence angle A1, which is a relatively low incidence angle, a shadow area may occur. That is, a thickness of the third direction DR3 of the first area L1 and/or the second area L1′ of the first layer may become thinner toward an edge thereof. The edge of the first area L1 of the first layer may overlap the third pixel-defining layer PDL3 in the third direction DR3. That is, the shadow area of the first area L1 of the first layer may overlap the third pixel-defining layer PDL3 in the third direction DR3.

Referring to FIG. 18, subsequently, the second layers L2 and L2′ are respectively formed on the first layers L1 and L1′ of the light-emitting structure EMS. The second layers L2 and L2′ may be separated into the first area L2 and the second area L2′ by the undercut structure or the void VD of the pixel-defining layer PDL. The first area L2 of the second layer may be formed on the first pixel-defining layer PDL1. The second area L2′ of the second layer may be formed on the third pixel-defining layer PDL3.

The second layers L2 and L2′ may be formed through a deposition process. For example, a material of the second layers L2 and L2′ may be vaporized at a deposition source and sprayed from a nozzle NZ to be deposited. Deposition material particles of the second layer L2 and L2′ may be sprayed from the nozzle NZ at a second incidence angle A2. In one or more embodiments, the second incidence angle A2 may be greater than the first incidence angle A1. The second incidence angle A2 may be about 80° or more, but is not necessarily limited thereto. As described above, a shadow effect may be improved by depositing the deposition material particles at the second incidence angle A2, which is a relatively high incidence angle. Accordingly, the thickness of the third direction DR3 of the first area L2 and/or the second area L2′ of the second layer may be formed to be uniform. As described above, the generation of the carrier that bypasses without contributing to light emission may be reduced or minimized by reducing or minimizing the thickness dispersion of some layers of the light-emitting structure EMS, for example, the second layer L2 and L2′, and thus the light emission efficiency may be improved as described above.

As the shadow area is decreased in the first area L2 of the second layer, the width in the first direction DR1 of the first area L2 of the second layer may be formed to be less than the width in the first direction DR1 of the first area L1 of the first layer. The first area L2 of the second layer may not overlap the third pixel-defining layer PDL3 in the third direction DR3. The edge of the first area L2 of the second layer may be aligned with the edge of the third pixel-defining layer PDL3 in the third direction DR3.

Referring to FIG. 19, subsequently, the third layers L3 and L3′ are respectively formed on the second layers L2 and L2′ of the light-emitting structure EMS. The third layer L3 and L3′ may be separated into the first area L3 and the second area L3′ by the undercut structure or the void VD of the pixel-defining layer PDL. The first area L3 of the third layer may be formed on the first pixel-defining layer PDL1. The second area L3′ of the third layer may be formed on the third pixel-defining layer PDL3.

The third layer L3 and L3′ may be formed through a deposition process. For example, a material of the third layer L3 and L3′ may be vaporized at a deposition source and sprayed from the nozzle NZ to be deposited. Deposition material particles of the third layer L3 and L3′ may be sprayed from the nozzle NZ at a third incidence angle A3. The third incidence angle A3 may be the same as the first incidence angle A1, but is not necessarily limited thereto. In one or more embodiments, the third incidence angle A3 may be about 50° or more, but is not necessarily limited thereto. As described above, when the deposition material particles are deposited at the third incidence angle A3, which is a relatively low incidence angle, a shadow area may occur. That is, the thickness of the third direction DR3 of the first area L3 and/or the second area L3′ of the third layer may become thinner toward their respective edges. The edge of the first area L3 of the third layer may not overlap the third pixel-defining layer PDL3 in the third direction DR3. For example, the edge of the first area L3 of the third layer may be aligned with the edge of the third pixel-defining layer PDL3 in the third direction DR3.

Subsequently, the cathode electrode CE may be formed on the light-emitting structure EMS, and thus the display device of FIGS. 1 to 15 may be completed.

According to the embodiments described above, a partial layer of the light-emitting structure EMS may be deposited at a high incidence angle and a remaining layer may be deposited at a low incidence angle, thereby improving a light emission efficiency and reducing a cost.

Although some embodiments are described herein, other embodiments and variations may be derived from the above description. Therefore, the spirit of the disclosure is not limited to these embodiments, and extends to the claims set forth below, various obvious modifications, and equivalents.

What is claimed is:

1. A display device comprising:
a first electrode;
a first pixel-defining layer above the first electrode;
a third pixel-defining layer above the first pixel-defining layer;
a void between the first pixel-defining layer and the third pixel-defining layer;
a light-emitting structure above the first electrode, the first pixel-defining layer, and the third pixel-defining layer, comprising a first layer and a second layer, and having a first area above the first pixel-defining layer, and a second area above the third pixel-defining layer, a width of the first layer at the first area being greater than a width of the second layer at the first area; and
a second electrode above the light-emitting structure.

2. The display device according to claim 1, wherein a thickness of the second layer at the first area is substantially uniform.

3. The display device according to claim 1, wherein a thickness of the first layer at the first area becomes thinner toward an edge thereof.

4. The display device according to claim 1, wherein the first area of the first layer overlaps the third pixel-defining layer.

5. The display device according to claim 1, wherein the first area of the second layer does not overlap the third pixel-defining layer.

6. The display device according to claim 1, wherein the first area and the second area are separated by the void.

7. The display device according to claim 1, wherein the first layer is between the first electrode and the second layer.

8. The display device according to claim 1, wherein the light-emitting structure further comprises a third layer above the second layer.

9. The display device according to claim 8, wherein the third layer at the first area does not overlap the third pixel-defining layer.

10. The display device according to claim 1, further comprising a second pixel-defining layer between the first pixel-defining layer and the third pixel-defining layer.

11. The display device according to claim 10, wherein a width of the second pixel-defining layer is less than a width of the first pixel-defining layer, and is less than a width of the third pixel-defining layer.

12. The display device according to claim 10, wherein a side surface of the void is defined by the second pixel-defining layer.

13. A method of manufacturing a display device, the method comprising:
forming a first pixel-defining layer above a first electrode;
forming a third pixel-defining layer above the first pixel-defining layer; and
forming a light-emitting structure above the first electrode, the first pixel-defining layer, and the third pixel-defining layer, by:
depositing a first layer at a first incidence angle; and
depositing a second layer above the first layer at a second incidence angle that is greater than the first incidence angle.

14. The method according to claim 13, wherein a void is between the first pixel-defining layer and the third pixel-defining layer.

15. The method according to claim 14, wherein the light-emitting structure comprises a first area and a second area separated by the void, the first area being above the first pixel-defining layer, and the second area being above the third pixel-defining layer.

16. The method according to claim 15, wherein a thickness of the second layer at the first area is substantially uniform.

17. The method according to claim 15, wherein a thickness of the first layer at the first area becomes thinner toward an edge thereof.

18. The method according to claim 17, wherein the edge of the first layer overlaps the third pixel-defining layer.

19. The method according to claim 15, wherein a width of the first layer at the first area is greater than a width of the second layer at the first area.

20. The method according to claim 13, further comprising forming a second pixel-defining layer between the first pixel-defining layer and the third pixel-defining layer that has a width that is less than a width of the first pixel-defining layer, and that is less than a width of the third pixel-defining layer.

21. An electronic device comprising:
a processor to provide input image data; and
a display device to display an image based on the input image data, the display device including sub-pixel areas,
wherein the display device comprises:
a first electrode;
a first pixel-defining layer above the first electrode;
a third pixel-defining layer above the first pixel-defining layer;
a void between the first pixel-defining layer and the third pixel-defining layer;
a light-emitting structure above the first electrode, the first pixel-defining layer, and the third pixel-defining layer, comprising a first layer and a second layer, and having a first area above the first pixel-defining layer, and a second area above the third pixel-defining layer, a width of the first layer at the first area being greater than a width of the second layer at the first area; and
a second electrode above the light-emitting structure.
